(19) United States
(12) Patent Application Publication
(10) Pub. No.: US 2025/0351628 A1
(43) Pub. Date: Nov. 13, 2025

(54) LIGHT-EMITTING DEVICE

(71) Applicant: KYOCERA Corporation, Kyoto-shi, Kyoto (JP)

(72) Inventor: Taro TAKEUCHI, Moriyama-shi, Shiga (JP)

(21) Appl. No.: 18/875,597

(22) PCT Filed: Jun. 5, 2023
(86) PCT No.: PCT/JP2023/020783

§ 371 Date: Dec. 16, 2024

(30) Foreign Application Priority Data
Jun. 21, 2022 (JP) 2022-099775

(51) Int. Cl. H10H 20/851; H10H 20/858

(52) U.S. Cl. CPC H10H 20/8512; H10H 20/8514; H10H 20/8582

(57) ABSTRACT

A light-emitting device includes a base member including a first surface, and a first recess on the first surface, a light emitter on a bottom surface of the first recess, and a wavelength converter in the first recess. The wavelength converter covers the light emitter and is in contact with an inner side surface (21c) of the first recess. The wavelength converter includes a plurality of wavelength conversion particles. An aspect ratio obtained by dividing a depth of the first recess by a maximum width of the bottom surface is greater than 1. The wavelength converter includes, on a surface of the wavelength converter opposite to a surface of the wavelength converter facing the bottom surface, a second recess recessed in a depth direction of the first recess.

### TECHNICAL FIELD

The present disclosure relates to a light-emitting device including a self-luminous element such as a light-emitting diode (LED).

### BACKGROUND OF INVENTION

A known light-emitting device is described in, for example, Patent Literature 1.

### CITATION LIST

### Patent Literature

Patent Literature 1: WO 2019/216333

### SUMMARY

In one or more aspects of the present disclosure, a light-emitting device includes a base member, a light emitter, and a wavelength converter. The base member includes a first surface and a first recess on the first surface. The light emitter is on a bottom surface of the first recess. The wavelength converter is in the first recess. The wavelength converter covers the light emitter and is in contact with an inner side surface of the first recess. The wavelength converter includes a plurality of wavelength conversion particles. An aspect ratio obtained by dividing a depth of the first recess by a maximum width of the bottom surface is greater than 1. The wavelength converter includes, on a surface of the wavelength converter opposite to a surface of the wavelength converter facing the bottom surface, a second recess recessed in a depth direction of the first recess.

### BRIEF DESCRIPTION OF THE DRAWINGS

The objects, features, and advantages of the present disclosure will become more apparent from the following detailed description and the drawings.

FIG. 1 is a plan view of a light-emitting device according to one embodiment of the present disclosure.

FIG. 2 is a cross-sectional view taken along section line II-II in FIG. 1.

FIG. 3A is a graph showing the relationship between the thickness of a wavelength converter in the light-emitting device in FIG. 1 and cavity efficiency.

FIG. 3B is a graph showing the relationship between the thickness of the wavelength converter in the light-emitting device in FIG. 1 and color gamut coverage.

FIG. 4 is a cross-sectional view of a light-emitting device according to another embodiment of the present disclosure.

FIG. 5 is a cross-sectional view of a light-emitting device according to another embodiment of the present disclosure.

FIG. 6 is a cross-sectional view of a light-emitting device according to another embodiment of the present disclosure.

FIG. 7 is a plan view of a display device including light-emitting devices according to one or more embodiments of the present disclosure.

FIG. 8 is a cross-sectional view taken along section line VIII-VIII in FIG. 7.

### DESCRIPTION OF EMBODIMENTS

Various light-emitting devices including self-luminous elements such as light-emitting diodes (LEDs) have been proposed. For example, Patent Literature 1 describes a light-emitting device including, in a space defined by a substrate and a reflector on the substrate, a light emitter, a first resin layer sealing the light emitter, and a second resin layer including quantum dots located on the first resin layer.

The known light-emitting device described in Patent Literature 1 may not effectively dissipate, out of the second resin layer, heat generated by the light emitter and transferred to the second resin layer. The quantum dots in the second resin layer may be degraded by the heat generated by the light emitter. The light-emitting device may not emit light with an intended wavelength spectrum.

A light-emitting device according to one or more embodiments of the present disclosure will now be described with reference to the accompanying drawings. Each figure referred to below illustrates the main components and other elements of the light-emitting device according to one or more embodiments. In one or more embodiments, the light-emitting device may include known components that are not illustrated, such as circuit boards, wiring conductors, control ICs, and LSI circuits. Some of the figures use an orthogonal XYZ coordinate system defined for convenience. A positive Z-direction is an upward direction in each figure, and the directional terms such as upward, downward, an upper surface, and a lower surface may be used accordingly.

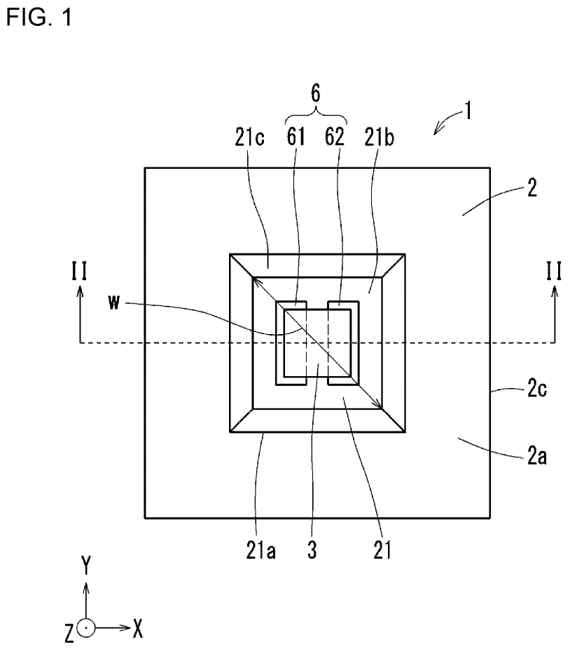

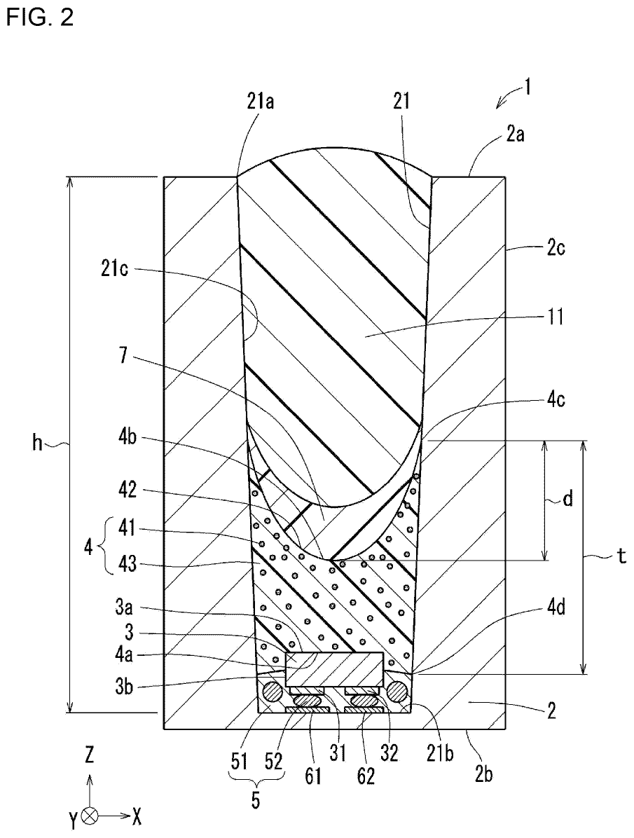

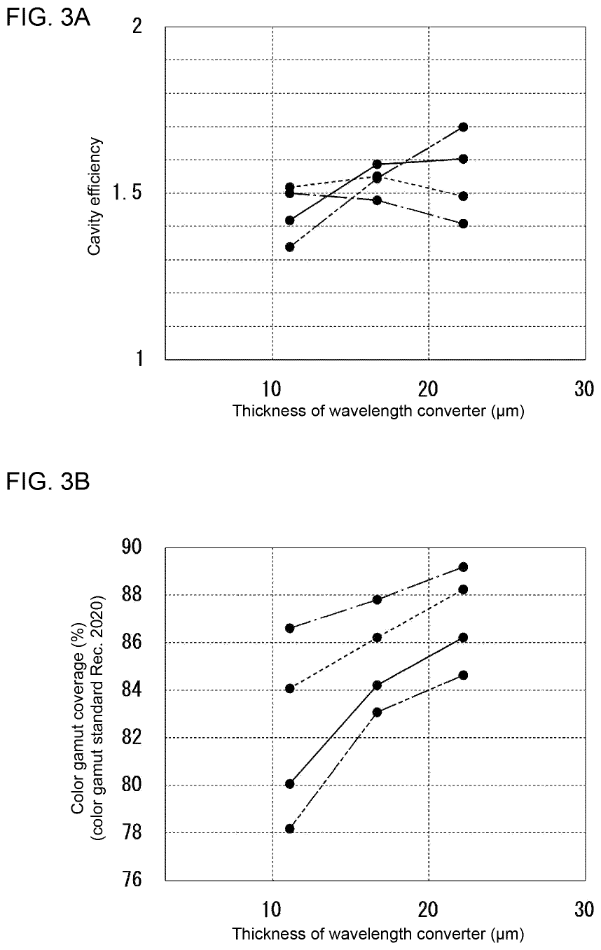

FIG. 1 is a plan view of a light-emitting device according to one embodiment of the present disclosure. FIG. 2 is a cross-sectional view taken along section line II-II in FIG. 1. FIG. 3A is a graph showing the relationship between the thickness of a wavelength converter in the light-emitting device in FIG. 1 and cavity efficiency. FIG. 3B is a graph showing the relationship between the thickness of the wavelength converter in the light-emitting device in FIG. 1 and color gamut coverage (under the color gamut standard Rec. 2020). In FIG. 1, components of the light-emitting device other than a base member, a light emitter, and electrode pads are not illustrated.

In one or more embodiments of the present disclosure, a light-emitting device 1 includes a base member 2, a light emitter 3, and a wavelength converter 4.

In one or more embodiments of the present disclosure, the light-emitting device 1 includes the base member 2 including a first surface 2a and a first recess 21 on the first surface 2a, and the light emitter 3 on a bottom surface 21b of the first recess 21. The light-emitting device 1 further includes the wavelength converter 4 in the first recess 21. The wavelength converter 4 covers the light emitter 3 and is in contact with an inner side surface 21c of the first recess 21. The wavelength converter 4 includes multiple wavelength conversion particles 41. The aspect ratio obtained by dividing a depth h of the first recess 21 by the maximum width of the bottom surface 21b is greater than 1. The wavelength converter 4 includes, on its surface (upper surface 4b) opposite to its surface (lower surface 4a) facing the bottom surface 21b, a second recess 42 recessed in a depth direction of the first recess 21.

In one or more embodiments of the present disclosure, the light-emitting device 1 with the above structure produces the effects described below. The wavelength converter 4 is in contact with the inner side surface 21c of the first recess 21. Thus, some of the numerous wavelength conversion particles 41 included in the wavelength converter 4 are also in contact with the inner side surface 21c. This allows heat generated by the light emitter 3 to be efficiently transferred and dissipated to the base member 2 through the wavelength converter 4 and some of the wavelength conversion particles 41 in contact with the inner side surface 21c of the first recess 21. The aspect ratio obtained by dividing the depth h of the first recess 21 by the maximum width of the bottom surface 21b is greater than 1. This increases the area of the inner side surface 21c of the first recess 21 and allows the first recess 21 to efficiently receive heat generated by the light emitter 3. This also increases the volume of the base member 2 and thus the heat capacity of the base member 2, allowing the base member 2 to efficiently receive heat generated by the light emitter 3. The structure also increases the convergence and directivity of light emitted from the light emitter 3 to outside. The wavelength converter 4 includes the second recess 42 recessed in the depth direction of the first recess 21 on the upper surface 4b opposite to the lower surface 4a facing the bottom surface 21b. This increases the area of the side surface of the wavelength converter 4 in contact with the inner side surface 21c of the first recess 21. This also increases the number of wavelength conversion particles 41 in contact with the inner side surface 21c of the first recess 21. Heat generated by the light emitter 3 is thus more efficiently transferred and dissipated to the base member 2 through the wavelength converter 4 and some of the wavelength conversion particles 41 in contact with the inner side surface 21c of the first recess 21.

The base member 2 is, for example, a plate or a block. As illustrated in FIGS. 1 and 2, the base member 2 includes one main surface (also referred to as the first surface) 2a, the other main surface 2b opposite to the main surface 2a, and a side surface 2c connecting the main surface 2a and the main surface 2b. The base member 2 may be made of, for example, a glass material, a ceramic material, a resin material, a metal material, or a semiconductor material. In the example in FIG. 1, the base member 2 is square as viewed in plan, but may be, for example, triangular, rectangular, trapezoidal, hexagonal, circular, oval, or in any other shape as viewed in plan. Being viewed in plan herein refers to being viewed in a direction perpendicular to the main surface 2a of the base member 2.

As illustrated in FIGS. 1 and 2, the base member 2 includes the first recess 21 that is open on the first surface 2a. The first recess 21 is recessed in a thickness direction (Z-direction) of the base member 2. As illustrated in FIG. 2, the first recess 21 includes an opening 21a, the bottom surface 21b, and the inner side surface 21c. The inner side surface 21c connects the opening 21a and the bottom surface 21b.

The first recess 21 may be, for example, square, rectangular, circular, oval, or in any other shape in a cross section taken along a plane parallel to the main surface 2a. The first recess 21 may have a size gradually decreasing from the main surface 2a to the main surface 2b in cross sections taken along planes parallel to the main surface 2a. As illustrated in FIG. 1, the first recess 21 may include peripheral edges of the opening 21a surrounding peripheral edges of the bottom surface 21b as viewed in plan.

As illustrated in, for example, FIG. 1, electrode pads 6 connected to the light emitter 3 are located on the bottom surface 21b of the first recess 21. The electrode pads 6 include an anode pad 61 and a cathode pad 62. The electrode pads 6 are connected to a drive circuit with a wiring conductor. The wiring conductor may include a feedthrough conductor extending partially through the base member 2 or may include a side conductor on the side surface 2c of the base member 2.

The drive circuit includes, for example, a thin-film transistor (TFT) and a wiring conductor. The TFT may include a semiconductor film made of, for example, amorphous silicon (a-Si) or low-temperature polycrystalline silicon (LTPS). The TFT may include three terminals, or specifically, a gate electrode, a source electrode, and a drain electrode. The TFT may serve as a switching element that switches conduction and non-conduction between the source electrode and the drain electrode based on the voltage applied to the gate electrode. The drive circuit may be formed using a thin film formation method such as chemical vapor deposition (CVD).

The light-emitting device 1 has an aspect ratio h/w greater than 1. The aspect ratio h/w is obtained by dividing the depth h of the first recess 21 by a maximum width w of the bottom surface 21b. This structure allows most of the light emitted from the light emitter 3 to be reflected at least once by the inner side surface 21c of the first recess 21. The light-emitting device 1 can thus emit light with higher directivity. This can further increase the luminance at a front surface (specifically, above the first recess 21) of the light-emitting device 1. The aspect ratio h/w of the first recess 21 may be, for example, about 2 to 3 or more. In this case, light emitted from the light emitter 3 can be reflected twice or more by the inner side surface 21c of the first recess 21. This can effectively increase the directivity of light emitted from the light-emitting device 1, further increasing the luminance at the front surface of the light-emitting device 1. When the bottom surface 21b is rectangular, the maximum width w may be the length of a diagonal line of the bottom surface 21b as illustrated in, for example, FIG. 1. When the bottom surface 21b is circular, the maximum width w may be the diameter of the bottom surface 21b. The maximum width w may be an absolute value of the square root of the area of the bottom surface 21b.

The light emitter 3 is located on the bottom surface 21b of the first recess 21. The light emitter 3 may be, for example, a self-luminous element such as an LED, an organic LED (OLED), or a semiconductor laser diode (LD). The light emitter 3 as an LED will now be described below: The light emitter 3 may be, for example, cubic, cuboid, cylindrical, or polygonal prismatic. The light emitter 3 may include an upper surface 3a facing the opening 21a of the first recess 21, and a side surface 3b facing the inner side surface 21c of the first recess 21. The light emitter 3 may be a micro-light-emitting diode (micro-LED). The micro-LED located on the bottom surface 21b may be rectangular with each side having a length of about 1 to 100 μm or about 5 to 20 μm, as viewed in plan. The upper surface 3a of the light emitter 3 may have a height of about 2 to 10 μm, about 4 to 8 μm, or about 6 μm from the bottom surface 21b.

The light emitter 3 includes an anode terminal 31 and a cathode terminal 32. The light emitter 3 may be connected to the electrode pads 6 by flip-chip connection. As illustrated in, for example, FIG. 2, the anode terminal 31 and the cathode terminal 32 may be respectively connected to the anode pad 61 and the cathode pad 62 with an anisotropic conductive film (ACF) 5 including an insulating resin 51 and conductive particles 52 dispersed in the insulating resin 51. The anode terminal 31 and the cathode terminal 32 may be respectively connected to the anode pad 61 and the cathode pad 62 with a conductive connector such as metal bumps, solder balls, or a conductive adhesive.

The light emitter 3 emits light with a wavelength λ0. The wavelength λ0 may correspond to blue light or ultraviolet (UV) light. Note that the light with the wavelength λ0 herein refers to monochromatic spectral light (monochromatic light) with the wavelength λ0 or continuous spectral light having an intensity peak at the wavelength λ0. The same or a similar structure applies to light with other wavelengths.

As illustrated in, for example, FIG. 2, the wavelength converter 4 is located in the first recess 21, covers the light emitter 3, and is in contact with the inner side surface 21c of the first recess 21. The wavelength converter 4 includes the multiple wavelength conversion particles 41. The wavelength conversion particles 41 convert the light at the wavelength λ0 emitted from the light emitter 3 to light at a wavelength λ that is longer than the wavelength 20. For the wavelength λ0 corresponding to blue light (at a wavelength of, for example, about 450 to 500 nm), the wavelength λ may correspond to red light (at a wavelength of, for example, about 620 to 750 nm) or green light (at a wavelength of, for example, about 500 to 570 nm). For the wavelength λ0 corresponding to UV light (at a wavelength of, for example, about 320 to 380 nm), the wavelength λ may correspond to red light, green light, or blue light.

The wavelength converter 4 may include about 100 to 10000 wavelength conversion particles 41. The wavelength converter 4 including fewer than 100 wavelength conversion particles 41 tends to have lower conversion efficiency. The wavelength converter 4 including more than 10000 wavelength conversion particles 41 can reach the conversion efficiency peak and tends to have lower efficiency of extracting light after wavelength conversion. The number of wavelength conversion particles 41 in the wavelength converter 4 may vary based on, for example, the type, shape, or average particle diameter of the wavelength conversion particles 41, and may not be 100 to 10000.

The wavelength conversion particles 41 may be phosphors or quantum dots. The phosphors may be made of an organic phosphor material such as a cyanine dye, a pyridine dye, or a rhodamine dye or made of an inorganic phosphor material such as (Sr, Ca)AlSiN₃:Eu, Y₂O₂S:Eu, or Y₂O₃:Eu. Note that the symbol: Eu refers to Eu being contained as a trace component. Each of the quantum dots may have a diameter of about 1 to 100 nm. The quantum dots may be made of a quantum dot material such as CdSe, CdS, or InP. The wavelength converter 4 including the wavelength conversion particles 41 as quantum dots can emit light with improved color purity.

The wavelength converter 4 includes a light-transmissive body 43. The wavelength conversion particles 41 are dispersed in the body 43. The wavelength conversion particles 41 may be evenly or unevenly dispersed in the body 43. The body 43 may be made of an insulating resin material or a glass material. Examples of the insulating resin material used for the body 43 include a fluororesin, a silicone resin, an acrylic resin, and an epoxy resin. Examples of the glass material used for the body 43 may include borosilicate glass, crystallized glass, quartz, and soda glass.

The wavelength converter 4 may be fabricated in the manner described below, for example. First, a light-transmissive insulating resin material in the form of liquid containing phosphors or quantum dots is injected into, through the opening 21a, the first recess 21 receiving the light emitter 3 with, for example, an inkjet method or a printing method. The insulating resin material injected into the first recess 21 is then irradiated with UV light or heated to be cured. This fabricates the wavelength converter 4. The insulating resin material may be irradiated with UV light or heated through the main surface 2b of the base member 2 to be cured.

As illustrated in, for example, FIG. 2, the wavelength converter 4 may be in contact with the upper surface 3a of the light emitter 3. For the wavelength converter 4 having a gap from the light emitter 3, light emitted from the light emitter 3 is scattered at the interface between the wavelength converter 4 and the gap. The light is thus less likely to be collected by the first recess 21 effectively. For the wavelength converter 4 being in contact with the upper surface 3a of the light emitter 3, the light can be effectively collected by the first recess 21. Note that the wavelength converter 4 may be in contact with the upper surface 3a and the side surface 3b of the light emitter 3. In this case, when the light emitter 3 is configured to emit light from the upper surface 3a and the side surface 3b, the wavelength of light emitted from the light emitter 3 can be effectively converted.

The wavelength converter 4 may be in contact with the entire upper surface 3a and the entire side surface 3b of the light emitter 3. In this case, when the light emitter 3 is configured to emit light from the upper surface 3a and the side surface 3b, the wavelength of light emitted from the light emitter 3 can be more effectively converted.

The wavelength converter 4 includes the surface (also referred to as the lower surface) 4a facing the bottom surface 21b and the surface (also referred to as the upper surface or a light-emitting surface) 4b opposite to the lower surface 4a. As illustrated in, for example, FIG. 2, the wavelength converter 4 includes, at the center of the upper surface 4b, the second recess 42 recessed in the depth direction (Z-direction) of the first recess 21. The second recess 42 has a depth d in the depth direction of the first recess 21. The wavelength converter 4 includes an upper end 4c closer to the first surface 2a and a lower end 4d closer to the bottom surface 21b. The upper end 4c is located between the first surface 2a and the bottom surface 21b in the depth direction (Z-direction) of the first recess 21. The distance between the upper end 4c and the lower end 4d in the depth direction of the first recess 21 is a maximum thickness t of the wavelength converter 4. The length (t-d) obtained by subtracting the depth d from the maximum thickness t is a center thickness tc at the center of the second recess 42. The center thickness tc is a thickness of a portion of the wavelength converter 4 excluding the second recess 42.

The second recess 42 may or may not be located at the center of the upper surface 4b of the wavelength converter 4. More specifically, the second recess 42 may include a deepest portion not located at the center of the upper surface 4b of the wavelength converter 4, but located slightly off the center of the upper surface 4b of the wavelength converter 4. For example, the deepest portion of the second recess 42 may be located laterally away from the center of the upper surface 4b of the wavelength converter 4 by about 1 to 30% of the length (width) of the upper surface 4b in the lateral direction (direction perpendicular to the depth direction).

The wavelength converter 4 is in contact with the inner side surface 21c of the first recess 21 and includes the second recess 42 on the light-emitting surface 4b. The wavelength converter 4 can thus have a larger surface area, particularly a larger contact area with the inner side surface 21c, than a comparative wavelength converter (hereafter referred to as a wavelength converter 4C) having the same center thickness tc as the wavelength converter 4 and including a flat light-emitting surface. This reduces thermal resistance of the wavelength converter 4, thus allowing the heat generated by the light emitter 3 and transferred to the wavelength converter 4 to be effectively dissipated to the base member 2.

For the center thickness tc being uniform and the depth d of the second recess 42 being larger, the wavelength converter 4 can have a larger surface area, particularly a larger contact area with the inner side surface 21c. For example, for the center thickness tc being 24 μm and the depth h of the first recess 21 being about 10 to 20 μm, the wavelength converter 4 can have a lower thermal resistance than the wavelength converter 4C by about 30 to 45%. The heat generated by the light emitter 3 and transferred to the wavelength converter 4 is effectively dissipated to the base member 2. In the manner described above, the light-emitting device 1 can have less wavelength fluctuations and less degradation of the wavelength conversion particles 41 resulting from heat generated by the light emitter 3. Thus, the light-emitting device 1 can emit light with an intended wavelength spectrum over a long period. Further, in the light-emitting device 1, the wavelength converter 4 is in contact with the light emitter 3, allowing the first recess 21 to effectively collect light to increase the luminance at the front surface of the light-emitting device 1.

The depth h of the first recess 21 may be greater than or equal to twice the maximum thickness t of the wavelength converter 4. In this case, most of the light emitted from the wavelength converter 4 can be reflected at least once by the inner side surface 21c of the first recess 21. This effectively increases the luminance at the front surface of the light-emitting device 1.

The wavelength converter 4 may satisfy 0.3≤d/(t−d)≤1. For d/(t−d) being greater than 1, the center thickness tc of the wavelength converter 4 is smaller, and light emitted from the light emitter 3 is less likely to interact with the wavelength conversion particles 41. For d/(t−d) being smaller than 0.3, heat is less likely to be dissipated, and light is less likely to be collected by the second recess 42. In the light-emitting device 1, when the wavelength converter 4 satisfies 0.3≤d/(t−d)≤1, heat can be dissipated more effectively, the light having an intended wavelength spectrum can be emitted, and the luminance at the front surface of the light-emitting device 1 can be increased.

As illustrated in, for example, FIG. 2, the light-emitting device 1 may include a color filter 7 on the light-emitting surface 4b of the wavelength converter 4. The color filter 7 may be in contact with the light-emitting surface 4b or spaced from the light-emitting surface 4b. The color filter 7 is configured to, for example, transmit the light at the wavelength λ emitted from the wavelength converter 4 and to absorb light (also referred to as unintended light) at wavelengths other than the wavelength λ. This improves the color purity of light emitted from the light-emitting device 1. The color filter 7 may not fully absorb unintended light. The color filter 7 may absorb unintended light emitted from the wavelength converter 4 to allow the unintended light through the color filter 7 to have an intensity not perceivable by humans.

The color filter 7 may be made of a (light-transmissive) resin material containing pigments or dyes. The pigments may be organic pigments or inorganic pigments. Examples of the resin material may include an acrylic resin, a polycarbonate resin, a silicone resin, and an epoxy resin.

The color filter 7 may be fabricated in the manner described below, for example. First, a resin material containing pigments or dyes is injected into, through the opening 21a, the first recess 21 receiving the light emitter 3 and the wavelength converter 4 with, for example, a printing method such as an inkjet method. The resin material injected into the first recess 21 is then irradiated with UV light or heated to be cured. This fabricates the color filter 7. The resin material may be irradiated with UV light or heated through the main surface 2b of the base member 2.

As illustrated in, for example, FIG. 2, the light-emitting device 1 may include a seal 11 on an upper surface (light-emitting surface) of the color filter 7. In this case, the first recess 21 is sealed hermetically to protect, for example, the light emitter 3 and the wavelength converter 4 in the first recess 21 from external environments such as humidity. In the structure including the seal 11, heat generated by the light emitter 3 is transferred from the wavelength converter 4 through the seal 11 to the base member 2, as well as from the wavelength converter 4 directly to the base member 2. As described above, heat generated by the light emitter 3 is transferred from the light emitter 3 to the base member 2 through more heat transfer paths, and is thus effectively dissipated to the base member 2. This effectively reduces degradation of the wavelength conversion particles 41 resulting from heat generated by the light emitter 3.

The seal 11 may be made of a light-transmissive resin material or a light-transmissive glass material. Examples of the resin material include a fluororesin, a silicone resin, an acrylic resin, and an epoxy resin. Examples of the glass material include borosilicate glass, crystallized glass, quartz, and soda glass.

The seal 11 may have a greater length in the depth direction of the first recess 21 than the sum of the length of the color filter 7 and the length of the body 43. In this case, the light-transmissive seal 11 absorbs less light, reduces light loss, and dissipates heat more effectively through the seal 11 to the base member 2. The length may be the maximum length or the average length. The length of the seal 11 in the depth direction of the first recess 21 may be, but not limited to, greater than one time and not more than about twenty times the sum of the lengths of the color filter 7 and the body 43 or greater than one time and not more than about five times the sum of the lengths of the color filter 7 and the body 43.

When the body 43 included in the wavelength converter 4 has a refractivity n1, the resin material included in the color filter 7 has a refractivity n2, and the seal 11 has a refractivity n3, n1<n2=n3 or n1<n2<n3 may be satisfied. These conditions allow light emitted from the light emitter 3 to be refracted toward the center of the color filter 7 at the boundary (hereafter referred to as a first boundary) between the body 43 and the color filter 7. Light emitted from the light emitter 3 can also be refracted toward the center of the seal 11 at the boundary (hereafter referred to as a second boundary) between the color filter 7 and the seal 11. In other words, the first boundary and the second boundary serve as lenses that cause convergence of light. This increases convergence (collection) of light emitted out of the first recess 21.

Further, n1<n3<n2 and (n2−n1)>(n3−n2) may be satisfied. In this case, the first boundary serves as a lens that causes convergence of light, whereas the second boundary slightly diffuses light. These conditions allow the convergence of the light emitted out of the first recess 21 to be adjusted to an optimal level.

FIG. 3A is the graph showing the relationship between the thickness of the wavelength converter 4 in the light-emitting device 1 and cavity efficiency. FIG. 3B is the graph showing the relationship between the thickness of the wavelength converter 4 in the light-emitting device 1 and color gamut coverage. In the graphs in FIGS. 3A and 3B, the thickness of the wavelength converter 4 refers to the center thickness tc. FIGS. 3A and 3B show results of simulation. In each of FIGS. 3A and 3B, the solid line indicates a result obtained when the depth d of the second recess 42 is set at 10 μm, the broken line indicates a result obtained when the depth d of the second recess 42 is set at 20 μm, and the dot-dash line indicates a result obtained when the depth d of the second recess 42 is set at 30 μm. The two-dot-dash line indicates a result for comparison, obtained when the light-emitting surface 4b of the wavelength converter 4 is flat.

The cavity efficiency in FIG. 3A is an index indicating the efficiency of extracting light from the light emitter 3. Higher cavity efficiency can increase the luminance at the front surface of the light-emitting device 1. The vertical axis in FIG. 3A indicates the ratio of second front luminance to first front luminance (second front luminance/first front luminance). The first front luminance is the luminance at the front surface of the light-emitting device 1 including the light emitter 3 alone and is 1, and the second front luminance is the luminance at the front surface of the light-emitting device 1 including the light emitter 3 located in the first recess 21 and covered with the wavelength converter 4. As shown in FIG. 3A, the wavelength converter 4 with the second recess 42 reduces a change in the cavity efficiency in response to a change in the center thickness tc of the wavelength converter 4. When multiple light-emitting devices 1 are manufactured, this structure reduces varying light-emitting characteristics among the multiple light-emitting devices 1 resulting from variation within the tolerance of the thickness of the wavelength converter 4. The light-emitting device 1 can thus have higher reliability. When multiple light-emitting devices 1 are combined into a display device, the multiple light-emitting devices 1 have less luminance variation to provide the display device with higher display quality.

The color gamut coverage in FIG. 3B is the color gamut coverage under the color gamut standard Rec. 2020 for the display device including a light-emitting device 1r, a light-emitting device 1g, and a light-emitting device 1b. The light-emitting device 1r refers to the light-emitting device 1 configured to emit red light. The light-emitting device 1g refers to the light-emitting device 1 configured to emit green light. The light-emitting device 1b refers to the light-emitting device 1 configured to emit blue light. Higher color gamut coverage increases the color purity of light emitted from the light-emitting devices 1r, 1g, and 1b. The wavelength converter 4 with the second recess 42 can increase the color gamut coverage. The second recess 42 with a greater depth d can increase the color gamut coverage.

The depth d of the second recess 42 may be greater than or equal to 10 μm. As shown in FIGS. 3A and 3B, the second recess 42 with a depth greater than or equal to 10 μm provides the display device with higher reliability, higher display quality, and higher color gamut coverage.

The wavelength converter 4 may have a higher density of the wavelength conversion particles 41 in its upper portion (specifically, a portion closer to the first surface 2a) than in its lower portion (specifically, a portion closer to the bottom surface 21b). In this case, the portion with the higher density of the wavelength conversion particles 41 can effectively transfer heat generated by the light emitter 3 laterally (perpendicularly to the depth direction) to efficiently dissipate the heat to the base member 2. Further, most of the wavelength conversion particles 41 can be away from the light emitter 3 to be less susceptible to the heat. This structure can also reduce the likelihood that light emitted from the light emitter 3 is emitted from the wavelength converter 4 without interacting with the wavelength conversion particles 41.

The density of the wavelength conversion particles 41 in the upper portion of the wavelength converter 4 may be, but not limited to, greater than one time and not more than about three times the density of the wavelength conversion particles 41 in the lower portion of the wavelength converter 4. The upper portion of the wavelength converter 4 with the higher density of the wavelength conversion particles 41 may have a thickness of, but not limited to, about 5 to 50% of the center thickness tc of the wavelength converter 4.

The wavelength converter 4 with its upper portion having the higher density of the wavelength conversion particles 41 may be formed in the manner described below; for example. A light-transmissive insulating resin material in the form of liquid containing phosphors or quantum dots as the wavelength conversion particles 41 is injected into, through the opening 21a, the first recess 21 receiving the light emitter 3 with, for example, an inkjet method or a printing method. The insulating resin material is then irradiated with UV light or heated through the main surface 2b of the base member 2 to be cured through the main surface 2b. As the insulating resin material is cured, most of the wavelength conversion particles 41 are pushed upward, forming a higher density portion of the wavelength conversion particles 41 in the upper portion of the wavelength converter 4.

The wavelength conversion particles 41 may include a first type of particles with a greater average particle diameter and a second type of particles with a smaller average particle diameter than the first type. The first type with the greater average particle diameter has higher viscosity resistance against the insulating resin material, and is thus easily pushed upward to form the higher density portion when the insulating resin material is cured through the main surface 2b. The average particle diameter of the first type may be, but not limited to, about 10 to 500 μm. The average particle diameter of the second type may be, but not limited to, about 0.1 to 100 μm. The ratio of the first type of particles to all the wavelength conversion particles 41 may be, but not limited to, about 10 to 90% by volume. The ratio of the second type of particles to all the wavelength conversion particles 41 may be, but not limited to, about 90 to 10% by volume.

A light-emitting device according to another embodiment of the present disclosure will now be described.

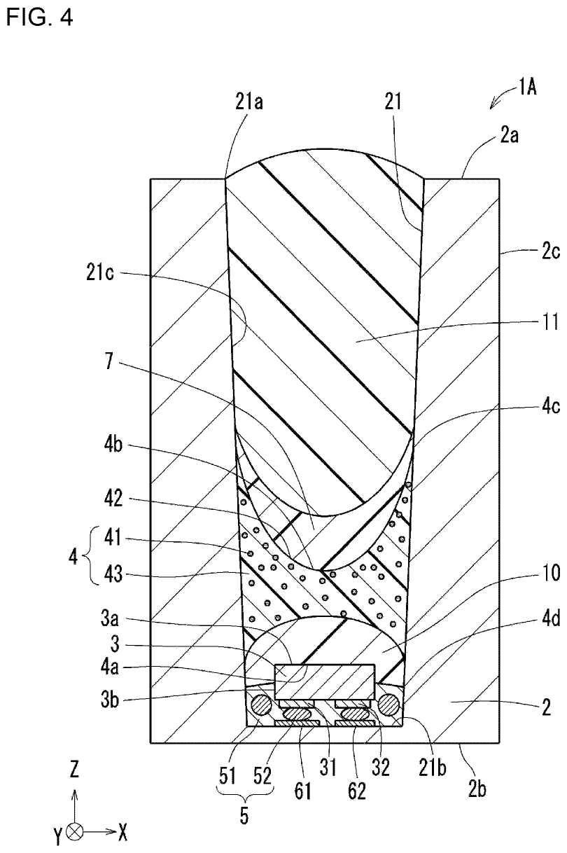

FIG. 4 is a cross-sectional view of a light-emitting device according to another embodiment of the present disclosure. The cross-sectional view in FIG. 4 corresponds to the cross-sectional view in FIG. 2. A light-emitting device 1A according to the present embodiment differs from the light-emitting device 1 in including a light-transmissive member 10. The other components that are the same as or similar to the components of the light-emitting device 1 are denoted with the same reference numerals and will not be described in detail.

As illustrated in, for example, FIG. 4, the light-emitting device 1A includes the light-transmissive member 10 between the light emitter 3 and the wavelength converter 4. The wavelength converter 4 covers the light emitter 3 with the light-transmissive member 10 between the wavelength converter 4 and the light emitter 3. This can reduce the likelihood that heat generated by the light emitter 3 is transferred to the wavelength converter 4, and thus reduce wavelength fluctuations and degradation of the wavelength conversion particles 41 resulting from heat generated by the light emitter 3. Further, the light-transmissive member 10 can reduce, for example, displacement of the light emitter 3 or separation of the light emitter 3 from the electrode pads 6. The light-emitting device 1A can provide a display device with higher long-term reliability.

The light-transmissive member 10 may be made of, for example, a transparent resin material such as a fluororesin, a silicone resin, an acrylic resin, a polycarbonate resin, or a polymethyl methacrylate resin.

The light-transmissive member 10 may be in contact with the upper surface 3a and the side surface 3b of the light emitter 3. The light-transmissive member 10 may be in contact with the inner side surface 21c of the first recess 21.

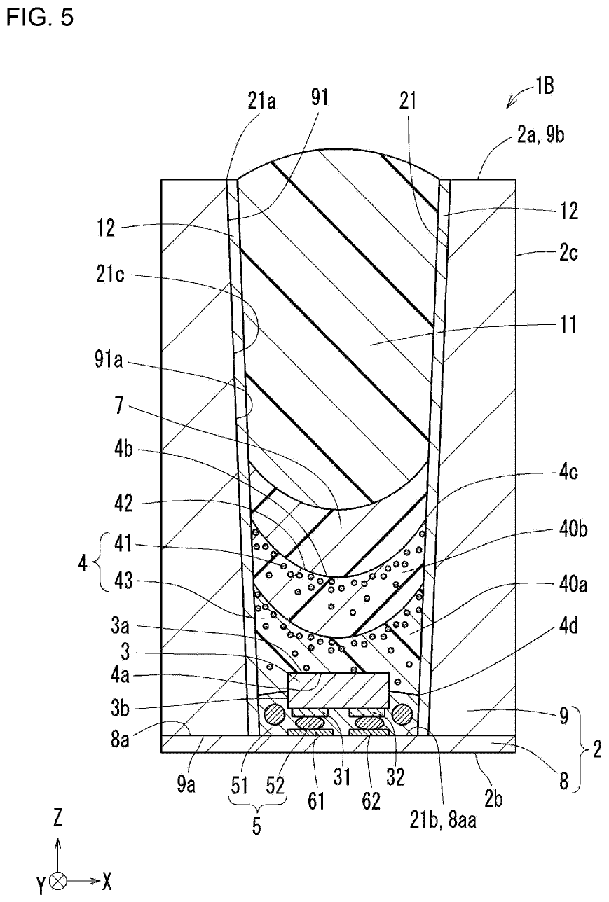

FIG. 5 is a cross-sectional view of a light-emitting device according to another embodiment of the present disclosure. The cross-sectional view in FIG. 5 corresponds to the cross-sectional view in FIG. 2. A light-emitting device 1B according to the present embodiment differs from the light-emitting device 1 in the structures of the wavelength converter 4 and the base member 2. The other components that are the same as or similar to the components of the light-emitting device 1 are denoted with the same reference numerals and will not be described in detail.

As illustrated in, for example, FIG. 5, the wavelength converter 4 in the light-emitting device 1B includes multiple wavelength converter layers 40a and 40b stacked on each other in the depth direction (Z-direction) of the first recess 21. In the wavelength converter 4, the density of the wavelength conversion particles 41 is lower at a position more away from the boundary between the adjacent wavelength converter layers 40a and 40b in the depth direction of the first recess 21. More specifically, the wavelength converter 4 includes a higher density portion in which the wavelength conversion particles 41 are distributed at higher density at the boundary between the adjacent wavelength converter layers 40a and 40b. In other words, the density of the wavelength conversion particles 41 is higher in the upper portion than in the lower portion in the single wavelength converter layer 40a or in the single wavelength converter layer 40b. This structure can reduce the likelihood that light emitted from the light emitter 3 is emitted from the wavelength converter 4 without interacting with the wavelength conversion particles 41. This improves the color purity of light emitted from the light-emitting device 1. Note that, although the wavelength converter 4 includes two wavelength converter layers 40a and 40b in the example in FIG. 5, the wavelength converter 4 may include three or more wavelength converter layers.

For the wavelength converter 4 with the structure in FIG. 5, the wavelength converter layers 40a and 40b may be sequentially formed by curing the respective insulating resin materials through the main surface 2b.

As illustrated in, for example, FIG. 5, the base member 2 may include a first substrate 8 and a second substrate 9. The first substrate 8 includes one main surface (also referred to as a second surface) 8a. The second surface 8a includes the bottom surface 21b of the first recess 21.

The first substrate 8 is made of, for example, a glass material, a ceramic material, a resin material, a metal material, or a semiconductor material. Examples of the glass material used for the first substrate 8 include borosilicate glass, crystallized glass, quartz, and soda glass. Examples of the ceramic material used for the first substrate 8 include alumina (Al₂O₃), aluminum nitride (AlN), silicon nitride (Si₃N₄), zirconia (ZrO₂), and silicon carbide (SiC). Examples of the resin material used for the first substrate 8 include an epoxy resin, a polyimide resin, and a polyamide resin. Examples of the metal material used for the first substrate 8 include aluminum (Al), titanium (Ti), beryllium (Be), magnesium (Mg) (particularly, high-purity magnesium with a Mg content of 99.95% or higher), zinc (Zn), Tin (Sn), copper (Cu), iron (Fe), chromium (Cr), nickel (Ni), and silver (Ag). The metal material used for the first substrate 8 may be an alloy material. Examples of the alloy material used for the first substrate 8 include an iron alloy mainly containing iron (a Fe—Ni alloy, a Fe—Ni—Co (cobalt) alloy, a Fe—Cr alloy, or a Fe—Cr—Ni alloy), duralumin, which is an aluminum alloy mainly containing aluminum (an Al—Cu alloy, an Al—Cu—Mg alloy, or an Al—Zn—Mg—Cu alloy), a magnesium alloy mainly containing magnesium (a Mg—Al alloy, a Mg—Zn alloy, or a Mg—Al—Zn alloy), titanium boride, and a Cu—Zn alloy. Examples of the semiconductor material used for the first substrate 8 include silicon (Si), germanium (Ge), and gallium arsenide (GaAs).

The first substrate 8 may be a single layer of, for example, the glass material, the ceramic material, the resin material, the metal material, or the semiconductor material described above, or may be a stack of multiple layers of any of these materials. For the first substrate 8 being a stack of multiple layers, the layers may be made of the same material or different materials.

The second substrate 9 includes one main surface (also referred to as a third surface) 9a and the other main surface (also referred to as a fourth surface) 9b opposite to the main surface 9a. The third surface 9a faces the second surface 8a of the first substrate 8. The fourth surface 9b is the first surface 2a of the base member 2.

The second substrate 9 includes a through-hole 91 extending through the second substrate 9 from the third surface 9a to the fourth surface 9b. The through-hole 91 exposes a portion (also referred to as a mounting surface) 8aa of the second surface 8a of the first substrate 8. The opening of the through-hole 91 in the fourth surface 9b is the opening 21a of the first recess 21. The mounting surface 8aa is the bottom surface 21b of the first recess 21. An inner side surface 91a of the through-hole 91 is the inner side surface 21c of the first recess 21. More specifically, the first recess 21 is defined by the inner side surface 91a of the through-hole 91 and the portion 8aa of the second surface 8a.

The second substrate 9 is made of, for example, a glass material, a ceramic material, a resin material, a metal material, or a semiconductor material.

Examples of the glass material used for the second substrate 9 include borosilicate glass, crystallized glass, quartz, and soda glass. Examples of the ceramic material used for the second substrate 9 include alumina, aluminum nitride, silicon nitride, zirconia, and silicon carbide. Examples of the resin material used for the second substrate 9 include an epoxy resin, a polyimide resin, and a polyamide resin. Examples of the metal material used for the second substrate 9 include aluminum, titanium, beryllium, magnesium (specifically, high-purity magnesium with a Mg content of 99.95% or higher), zinc, tin, copper, iron, chromium, nickel, and silver. The metal material used for the second substrate 9 may be an alloy material. Examples of the alloy material used for the second substrate 9 include an iron alloy mainly containing iron (a Fe—Ni alloy, a Fe—Ni—Co alloy, a Fe—Cr alloy, or a Fe—Cr—Ni alloy), duralumin, which is an aluminum alloy mainly containing aluminum (an Al—Cu alloy, an Al—Cu—Mg alloy, or an Al—Zn—Mg—Cu alloy), a magnesium alloy mainly containing magnesium (a Mg—Al alloy, a Mg—Zn alloy, or a Mg—Al—Zn alloy), titanium boride, and a Cu—Zn alloy. Examples of the semiconductor material used for the second substrate 9 include silicon, germanium, and gallium arsenide.

The second substrate 9 may be a single layer of, for example, the glass material, the ceramic material, the resin material, the metal material, or the semiconductor material described above, or may be a stack of multiple layers of any of these materials. For the second substrate 9 being a stack of multiple layers, the layers may be made of the same material or different materials. The through-hole 91 may be formed by, for example, punching, electroforming (plating), cutting, or laser beam machining. For the second substrate 9 made of a metal material, the through-hole 91 may be formed by, for example, punching or electroforming. For the second substrate 9 made of a semiconductor material, the through-hole 91 may be formed by, for example, photolithography including dry etching.

For the second substrate 9 made of a metal material or a semiconductor material, an insulator or an insulating layer made of an electrically insulating material may be located between the second surface 8a of the first substrate 8 and the third surface 9a of the second substrate 9. This can reduce short-circuiting between electrodes, wiring conductors, or other components on the second surface 8a of the first substrate 8 through the second substrate 9. Examples of the electrically insulating material used for the insulator or the insulating layer include silicon oxide and silicon nitride.

In the light-emitting device 1B, the second substrate 9 may be thicker than the first substrate 8. In this case, light emitted from the light emitter 3 can be reflected by the inner side surface 91a of the through-hole 91. This can increase the directivity of light emitted from the light-emitting device 1B and thus increase the luminance at a front surface of the light-emitting device 1B. The thickness of the second substrate 9 may be, but not limited to, greater than one time and not more than about ten times the thickness (e.g., about 0.1 to 5 mm) of the first substrate 8.

In the light-emitting device 1B, the second substrate 9 may have a higher thermal conductivity than the first substrate 8. In this case, heat generated by the light emitter 3 is effectively dissipated to the second substrate 9 through the wavelength converter 4, thus reducing degradation of the wavelength conversion particles 41. The light-emitting device 1B can thus emit light with an intended wavelength spectrum over a long period. The thermal conductivity of the second substrate 9 may be, but not limited to, greater than one time and not more than about 1000 times the thermal conductivity of the first substrate 8. For example, when the first substrate 8 is made of, for example, soda glass (thermal conductivity α=1.03 W/(m·K)), borosilicate glass (α=1.10), quartz glass (α=1.38), an acrylic resin (α=0.21), an epoxy resin (α=0.30), polyethylene (α=0.34), polystyrene (α=0.15), an alumina ceramic (α=36.0), a titanium ceramic (α=8.4), or a zirconia ceramic (α=3.1), the second substrate 9 may be made of, for example, aluminum (α=237), silicon (α=148), copper (α=398), stainless steel (α=12.8 to 27.0), Inconel (α=12.0 to 14.8), an aluminum alloy (α=120 to 193) containing at least one selected from the group consisting of Cu, Cr, Mn, Mg, and Zn, brass (α=121 to 123), a gallium arsenide compound semiconductor (α=54), or a zinc selenide compound semiconductor (α=19).

Note that, in the example in FIGS. 2 and 4, each of the base members 2 in the light-emitting devices 1 and 1A is a single member, but may include the first substrate 8 and the second substrate 9 in the same manner as or in a similar manner to the base member 2 in the light-emitting device 1B.

As illustrated in, for example, FIG. 5, the second substrate 9 may include a light reflective film 12 on the inner side surface 91a of the through-hole 91. This structure increases light reflectivity in the first recess 21 and reduces light loss when light emitted from the light emitter 3 is reflected in the first recess 21. This increases the efficiency of extracting light emitted from the light emitter 3. The wavelength converter 4 may be in contact with the light reflective film 12 and may be in contact with the inner side surface 21c of the first recess 21 through the light reflective film 12.

The light reflective film 12 may be made of, for example, a metal material. Examples of the metal material used for the light reflective film 12 may include aluminum, silver, and gold. The light reflective film 12 may be formed on the inner side surface 21c of the first recess 21 with a thin film formation method such as CVD, vapor deposition, or plating. The light reflective film 12 may be formed with a thick film forming method that includes firing and solidifying a resin paste including particles of a metal material such as aluminum, silver, or gold. The light reflective film 12 may be formed by bonding a film containing, for example, aluminum, silver, or gold to the inner side surface 21c of the first recess 21.

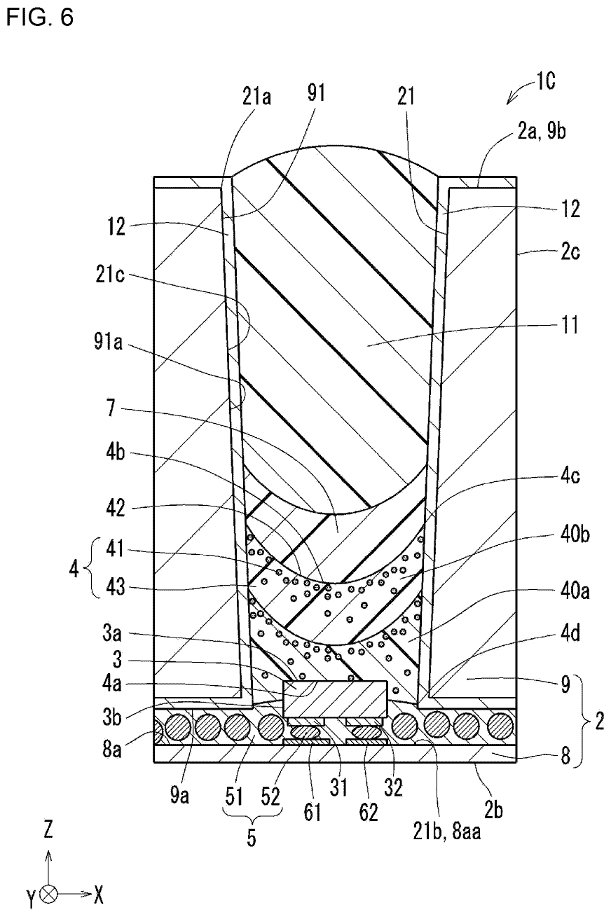

FIG. 6 is a cross-sectional view of a light-emitting device according to another embodiment of the present disclosure. The cross-sectional view in FIG. 6 corresponds to the cross-sectional view in FIG. 2. A light-emitting device 1C according to the present embodiment differs from the light-emitting device 1B in the structure of the base member 2. The other components that are the same as or similar to the components of the light-emitting device 1B are denoted with the same reference numerals and will not be described in detail.

As illustrated in, for example, FIG. 6, the first substrate 8 and the second substrate 9 in the light-emitting device 1C are spaced from each other in the thickness direction (Z-direction) of the base member 2 with the ACF 5 between the first substrate 8 and the second substrate 9. In this case, the second substrate 9 can have a greater thickness in its portion for reflecting light emitted from the light emitter 3. This can increase the directivity of light emitted from the light-emitting device 1C and thus increase the luminance at a front surface of the light-emitting device 1C. When the light-emitting device 1C includes the light-transmissive member 10, the light-transmissive member 10 may extend between the first substrate 8 and the second substrate 9. The light-transmissive member 10 may extend between the third surface 9a of the second substrate 9 and the ACF 5.

When the first substrate 8 and the second substrate 9 are spaced from each other, the light reflective film 12 may extend from the inner side surface 91a of the through-hole 91 to the third surface 9a and the fourth surface 9b of the second substrate 9, as illustrated in, for example, FIG. 6. This allows the heat generated by the light emitter 3 and transferred to the wavelength converter 4 to be dissipated effectively to the entire second substrate 9. This reduces degradation of the wavelength conversion particles 41. The light-emitting device 1C can emit light with an intended wavelength spectrum over a long period.

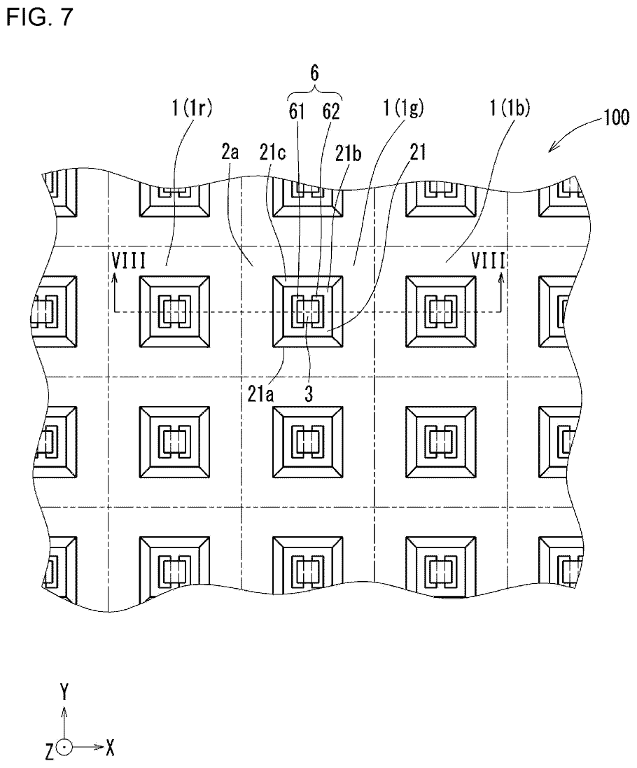

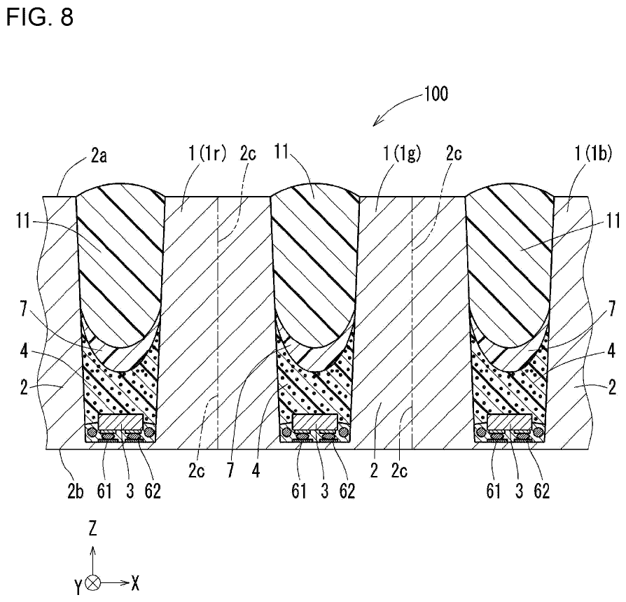

A display device 100 including light-emitting devices 1 will now be described. FIG. 7 is a plan view of a display device including light-emitting devices according to one or more embodiments of the present disclosure. FIG. 8 is a cross-sectional view taken along section line VIII-VIII in FIG. 7. In FIG. 7, components of each of the light-emitting devices other than the base member, the light emitter, and the electrode pads are not illustrated.

The display device 100 includes multiple light-emitting devices 1. As illustrated in, for example, FIG. 7, the multiple light-emitting devices 1 are arranged in a matrix. As illustrated in, for example, FIG. 8, the multiple light-emitting devices 1 may include the first surfaces 2a of the base members 2 located on a single imaginary plane. The side surfaces 2c of the multiple light-emitting devices 1 adjacent to one another may be bonded (tiled) to one another with a bond, such as an inorganic adhesive or an organic adhesive.

The display device 100 may include multiple pixels. Each of the pixels may include multiple light-emitting devices 1. Each of the pixels may be, for example, the light-emitting device 1r configured to emit red light, the light-emitting device 1g configured to emit green light, or the light-emitting device 1b configured to emit blue light. In this case, the display device 100 can display full-color gradation.

The display device 100 including the multiple light-emitting devices 1 can have less variation in light-emitting characteristics among the multiple light-emitting devices 1 and higher color gamut coverage. As described above, the multiple light-emitting devices 1 are combined to provide the display device 100 with higher display quality. In FIGS. 7 and 8, the display device 100 includes the multiple light-emitting devices 1, but may include multiple light-emitting devices 1A, multiple light-emitting devices 1B, or multiple light-emitting devices 1C.

As described above, in one or more embodiments of the present disclosure, the light-emitting device can effectively dissipate heat generated by the light emitter to the base member, thus reducing wavelength fluctuations and degradation of the wavelength conversion particles resulting from heat. Thus, in one or more embodiments of the present disclosure, the light-emitting device can emit light with an intended wavelength spectrum over a long period.

The technique according to one or more embodiments of the present disclosure may have aspects (1) to (10) described below.

(1) A light-emitting device, comprising:
a base member including a first surface, and a first recess on the first surface;
a light emitter on a bottom surface of the first recess; and
a wavelength converter in the first recess, the wavelength converter covering the light emitter and being in contact with an inner side surface of the first recess, the wavelength converter including a plurality of wavelength conversion particles,
wherein an aspect ratio obtained by dividing a depth of the first recess by a maximum width of the bottom surface is greater than 1, and
the wavelength converter includes, on a surface of the wavelength converter opposite to a surface of the wavelength converter facing the bottom surface, a second recess recessed in a depth direction of the first recess.

(2) The light-emitting device according to (1), wherein
the depth of the first recess is greater than or equal to twice a maximum thickness of the wavelength converter in the depth direction.

(3) The light-emitting device according to (2), wherein
the wavelength converter satisfies 0.3≤d/(t-d)≤1, where d is a depth of the second recess, and t is the maximum thickness.

(4) The light-emitting device according to (3), wherein
the depth of the second recess is greater than or equal to 10 μm.

(5) The light-emitting device according to any one of (1) to (4), further comprising:
a light-transmissive member between the light emitter and the wavelength converter.

(6) The light-emitting device according to any one of (1) to (5), wherein
the wavelength converter has higher density of the plurality of wavelength conversion particles in a portion closer to the first surface than in a portion closer to the bottom surface.

(7) The light-emitting device according to any one of (1) to (6), wherein
the wavelength converter includes a plurality of wavelength converter layers stacked on one another in the depth direction, and
a density of the plurality of wavelength conversion particles is lower at a position more away from a boundary between adjacent wavelength converter layers of the plurality of wavelength converter layers in the depth direction.

(8) The light-emitting device according to any one of (1) to (7), wherein
the base member includes a first substrate including a second surface, and a second substrate on the second surface, and the second substrate includes a third surface facing the second surface, and a fourth surface opposite to the third surface,
the second substrate includes a through-hole extending through the second substrate from the third surface to the fourth surface, and the through-hole exposes a portion of the second surface, and
the first recess is defined by an inner surface of the through-hole and the portion of the second surface.

(9) The light-emitting device according to (8), wherein
the second substrate is thicker than the first substrate.

(10) The light-emitting device according to (8) or (9), wherein
the second substrate has a higher thermal conductivity than the first substrate.

Although one or more embodiments of the present disclosure have been described in detail, the present disclosure is not limited to the embodiments described above, and may be changed or varied in various manners without departing from the spirit and scope of the present disclosure. The components described in the above embodiments may be entirely or partially combined as appropriate unless any contradiction arises.

### INDUSTRIAL APPLICABILITY

The light-emitting device according to one or more embodiments of the present disclosure may be used in various electronic devices as, for example, a display device or an indicator. Such electronic devices include automobile route guidance systems (car navigation systems), ship route guidance systems, aircraft route guidance systems, indicators for instruments in vehicles such as automobiles, instrument panels, smartphones, mobile phones, tablets, personal digital assistants (PDAs), video cameras, digital still cameras, electronic organizers, electronic books, electronic dictionaries, personal computers, copiers, terminals for game devices, television sets, product display tags, price display tags, programmable display devices for industrial use, car audio systems, digital audio players, facsimile machines, printers, automatic teller machines (ATMs), vending machines, medical display devices, digital display watches, smartwatches, guidance display devices installed in stations or airports, and signage (digital signage) for advertisement.

### REFERENCE SIGNS

1, 1r, 1g, 1b, 1A, 1B, 1C light-emitting device
2 base member
2a one main surface (first surface)
2b other main surface
2c side surface
21a opening
21b bottom surface
21c inner side surface
21 first recess
3 light emitter
3a upper surface
3b side surface
31 anode terminal
32 cathode terminal
4 wavelength converter
4a lower surface
4b upper surface (light-emitting surface)
4c upper end
4d lower end
40a, 40b wavelength converter layer
41 wavelength converting particle
42 second recess
43 body
5 anisotropic conductive film (ACF)
51 insulating resin
52 conductive particle
6 electrode pad
61 anode pad
62 cathode pad
7 color filter
8 first substrate
8a one main surface (second surface)
8aa mounting surface
9 second substrate
9a one main surface (third surface)
9b other main surface (fourth surface)
91 through-hole
91a inner side surface
10 light-transmissive member
11 seal
12 light reflective film
100 display device

1. A light-emitting device, comprising:
a base member including a first surface, and a first recess on the first surface;
a light emitter on a bottom surface of the first recess; and
a wavelength converter in the first recess, the wavelength converter covering the light emitter and being in contact with an inner side surface of the first recess, the wavelength converter including a plurality of wavelength conversion particles,
wherein an aspect ratio obtained by dividing a depth of the first recess by a maximum width of the bottom surface is greater than 1, and
the wavelength converter includes, on a surface of the wavelength converter opposite to a surface of the wavelength converter facing the bottom surface, a second recess recessed in a depth direction of the first recess.

2. The light-emitting device according to claim 1, wherein
the depth of the first recess is greater than or equal to twice a maximum thickness of the wavelength converter in the depth direction.

3. The light-emitting device according to claim 2, wherein
the wavelength converter satisfies 0.3≤d/(t−d)≤1, where d is a depth of the second recess, and t is the maximum thickness.

4. The light-emitting device according to claim 3, wherein
the depth of the second recess is greater than or equal to 10 μm.

5. The light-emitting device according to claim 1, further comprising:
a light-transmissive member between the light emitter and the wavelength converter.

6. The light-emitting device according to claim 1, wherein
the wavelength converter has higher density of the plurality of wavelength conversion particles in a portion closer to the first surface than in a portion closer to the bottom surface.

7. The light-emitting device according to claim 1, wherein
the wavelength converter includes a plurality of wavelength converter layers stacked on one another in the depth direction, and
a density of the plurality of wavelength conversion particles is lower at a position more away from a boundary between adjacent wavelength converter layers of the plurality of wavelength converter layers in the depth direction.

8. The light-emitting device according to claim 1, wherein
the base member includes a first substrate including a second surface, and a second substrate on the second surface, and the second substrate includes a third surface facing the second surface, and a fourth surface opposite to the third surface,
the second substrate includes a through-hole extending through the second substrate from the third surface to the fourth surface, and the through-hole exposes a portion of the second surface, and
the first recess is defined by an inner surface of the through-hole and the portion of the second surface.

9. The light-emitting device according to claim 8, wherein
the second substrate is thicker than the first substrate.

10. The light-emitting device according to claim 8, wherein the second substrate has a higher thermal conductivity than the first substrate.
